(19) United States
(12) Patent Application Publication
(10) Pub. No.: US 2009/0295837 A1
(43) Pub. Date: Dec. 3, 2009

(54) CIRCUIT FOR GENERATING DRIVE VOLTAGE

(75) Inventor: Chia-Bo LIN, Taipei City (TW)

Correspondence Address: Muncy, Geissler, Olds & Lowe, PLLC, P.O. BOX 1364, FAIRFAX, VA, 22038-1364, US

(73) Assignee: PRINCETON TECHNOLOGY CORPORATION

(21) Appl. No.: 12/173,590

(22) Filed: Jul. 15, 2008

(30) Foreign Application Priority Data
May 27, 2008 (TW) 097119491

(51) Int. Cl. G09G 5/00; H03B 1/00

(52) U.S. Cl. 345/690; 327/108

(57) ABSTRACT

The invention provides a circuit for generating a drive voltage. The circuit of the invention includes a first current generating unit coupled between a voltage source and a ground for generating a first input current. A comparing unit having a first input terminal coupled to the first current generating unit and a second input terminal coupled to an output terminal thereof. The comparing unit is used for comparing the first input current with a second input current and generating an output voltage. A second current generating unit is coupled between the output terminal and the second input terminal of the comparing unit for generating the second input current. An adjusting unit is coupled to the second input terminal of the comparing unit, the second current generating unit and the ground for adjusting the second input current. The voltage level of the output voltage is controlled by the adjusting unit.

### BACKGROUND OF THE INVENTION

This Application claims priority of Taiwan Patent Application No. 097119491, filed on May 27, 2008, the entirety of which is incorporated by reference herein.

### FIELD OF THE INVENTION

The invention relates to a circuit for generating a drive voltage, and more particularly to a drive voltage generating circuit for a display device.

### DESCRIPTION OF THE RELATED ART

FIG. 1 is a circuit diagram illustrating a circuit 100 for generating a drive voltage according to the prior art. The circuit 100 comprises a plurality of resistors coupled in series between a voltage source V_{DD} and a ground V_{SS}, a plurality of transmission gates (T₁, T₂, T₃, T₄, T₅, T₆ and T₇) and a unity gain buffer amplifier 102. Further, the circuit 100 according to the prior art comprises a control circuit (not shown) for generating a plurality of control signals (C₁, C₂, C₃, C₄, C₅, C₆ and C₇) to, respectively control said transmission gates (T₁, T₂, T₃, T₄, T₅, T₆ and T₇). A user is able to change the voltage level of a node 104 by, respectively turning on said transmission gates (T₁, T₂, T₃, T₄, T₅, T₆ and T₇), thereby obtaining an output voltage Vₒᵤₜ of the circuit 100. The unity gain buffer amplifier 102 is coupled between the node 104 and an output terminal of the circuit 100 for preventing a drift in the output voltage Vₒᵤₜ induced by driving a load.

As shown in FIG. 1, the conventional circuit 100 supplies a drive voltage with different voltage levels according to the voltage division, which takes place at each terminal from the plurality of series-connected resistors (R) The conventional circuit 100 shown in FIG. 1 requires at least 8 resistors and 7 transmission gates (T₁, T₂, T₃, T₄, T₅, T₆ and T₇) to be able to supply a voltage with 7 voltage levels for the node 104. Also, it is necessary for the control circuit to generate 7 control signals (C₁, C₂, C₃, C₄, C₅, C₆ and C₇) to drive the plurality of transmission gates (T₁, T₂, T₃, T₄, T₅, T₆ and T₇), respectively. Thus, the invention discloses a novel and improved circuit for generating a drive voltage.

### BRIEF SUMMARY OF THE INVENTION

The invention provides a circuit for generating a drive voltage, comprising a voltage source, a first current generating unit, a comparing unit, a second current generating unit and an adjusting unit. The first current generating unit is coupled to the voltage source and a ground for generating a first input current. The comparing unit has a first input terminal, a second input terminal and an output terminal, wherein the first input terminal is coupled to the first current generating unit, the second input terminal is coupled to the output terminal, and an output voltage is generated by comparing the first input current with a second input current. The second current generating unit is coupled between the output terminal and the second input terminal of the comparing unit for generating the second input current. The adjusting unit is coupled to the second input terminal of the comparing unit, the second current generating unit and the ground for adjusting the second input current. The output terminal of the comparing unit is an output terminal of the circuit for generating the drive voltage and the voltage level of the output voltage is controlled by the adjusting unit.

Moreover, the circuit for generating the drive voltage according to the invention is provided for driving a liquid crystal display device and adjusting a display contrast of the liquid crystal display device.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a circuit diagram illustrating a circuit 100 for generating a drive voltage according to the prior art;

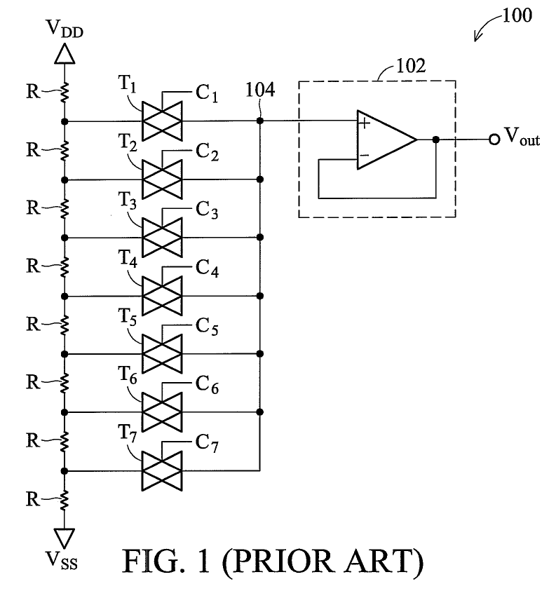

FIG. 2 is block diagram illustrating a circuit for generating a drive voltage according to the invention;

FIG. 3 is block diagram illustrating a circuit for generating a drive voltage according an embodiment of the invention; and

FIG. 4 is block diagram illustrating a circuit for generating a drive voltage according a preferred embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

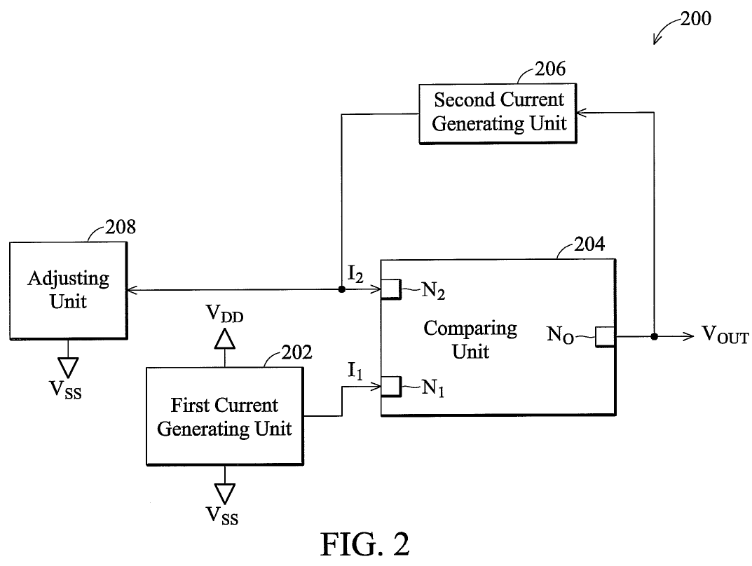

Please refer to FIG. 2. FIG. 2 is block diagram illustrating a circuit for generating a drive voltage according to the invention. As shown in FIG. 2, the circuit 200 for generating a drive voltage comprises a voltage source V_{DD}, a first current generating unit 202, a comparing unit 204, a second current generating unit 206 and an adjusting unit 208. The first current generating unit 202 is coupled to the voltage source V_{DD} and a ground V_{SS} for supplying a first input current I₁. The comparing unit 204 has a first input terminal N₁, a second input terminal N₂ and an output terminal N₀. The first input terminal N₁ is coupled to the first current generating unit 202. The second input terminal N₂ is coupled to the output terminal N₀. The comparing unit 204 obtains an output voltage Vₒᵤₜ by comparing the first input current I₁ with a second input current I₂. The second current generating unit 206 is coupled between the output terminal N₀ and the second input terminal N₂ of the comparing unit 204 for generating the second input current I₂. The adjusting unit 208 is coupled to the second input terminal N₂ of the comparing unit 204, the second current generating unit 206 and the ground V_{SS} for adjusting the second input current I₂. Further, the output terminal N₀ of the comparing unit 204 is an output terminal of the circuit 200 for generating the drive voltage and the voltage level of the output voltage Vₒᵤₜ is controlled by the adjusting unit 208. In an embodiment, the circuit 200 for generating the drive voltage according to the invention is provided for driving a liquid crystal display device, thereby adjusting a display contrast of the liquid crystal display device.

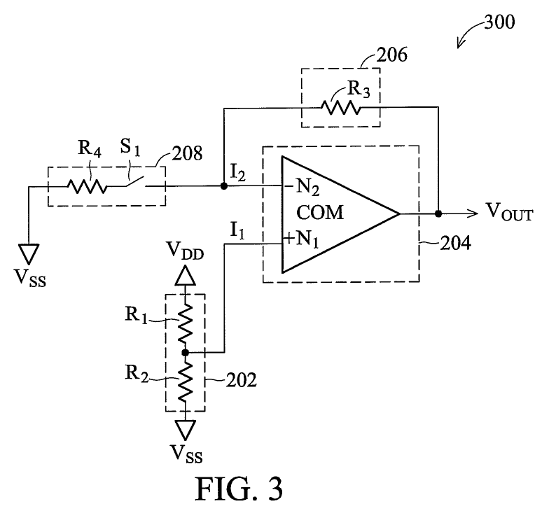

Please refer to FIG. 3. FIG. 3 is block diagram illustrating a circuit for generating a drive voltage according an embodiment of the invention. Referring to FIGS. 2 and 3, the first current generating unit 202 comprises at least two resistors R₁ and R₂. The at least two resistors R₁ and R₂ are connected in series between the voltage source V_{DD} and the ground V_{SS} for supplying the first input current I₁. The comparing unit 204 is a comparator COM. A first input terminal N₁ and a second input terminal N₂ are a negative terminal (−) and a positive terminal (+) of the comparator COM, respectively. The second current generating unit 206 is a resistor R₃ and the adjusting unit 208 comprises at least one resistor R₄, at least one switch S₁ and a control circuit (not shown). One terminal of the at least one resistor R₄ is coupled to the ground V_{SS}. One terminal of the at least one switch S₁ is coupled to the other terminal of the at least one resistor R₄ and the other terminal of the at least one switch S₁ is coupled to the second input terminal N₂ of the comparator COM. The control circuit (not shown) generates at least one control signal S_{c} to turn on or turn off the at least one switch S₁, thereby controlling the second input current I₂ by determining whether the current passes through the at least one resistor R₄. With the control of the second input current I₂, the output voltage Vₒᵤₜ is further generated from the comparing unit 204 by comparing the first input current I₁ and the second input current I₂. Finally, the object of controlling the output voltage Vₒᵤₜ is achieved.

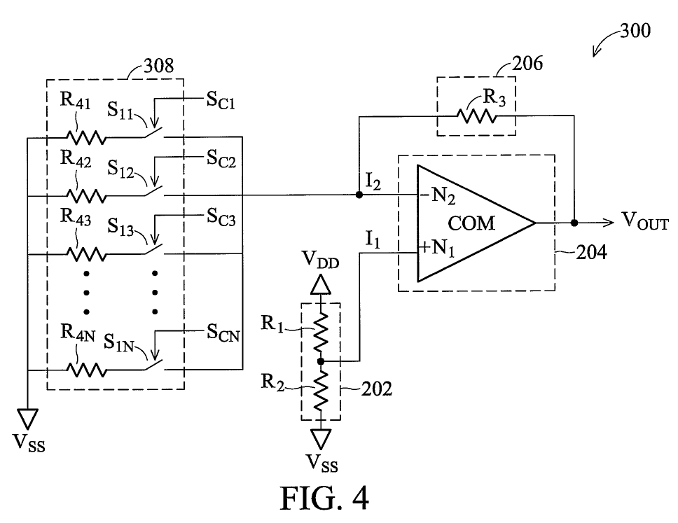

Please refer to FIG. 4. FIG. 4 is block diagram illustrating a circuit for generating a drive voltage according a preferred embodiment of the invention. As shown in FIG. 4, the circuit 300 for generating a drive voltage comprises a plurality of resistors R₄₁˜R_{4N}, a plurality of switches S₁₁˜S_{1N} corresponding to the plurality of resistors R₄₁˜R_{4N}, and a control circuit (not shown). A plurality of control signals S_{C1}˜S_{CN} output from the control circuit (not shown) determine whether to turn-on or turn-off the plurality of switches S₁₁˜S_{1N}. The second input current I₂ of the comparator COM varies with the state of the plurality of switches S11˜S1N (e.g. on or off). Accordingly, the circuit 300 for generating a drive voltage supplies different output voltages Vₒᵤₜ according to different second input currents I₂ received from the comparator COM.

According to the invention, the circuit for generating a drive voltage is provided for driving a liquid crystal display device and adjusting a display contrast of the liquid crystal display device. For example, from the circuit 300 for generating a drive voltage shown in FIG. 4, there are N different display contrast settings for the liquid crystal display device in response to N different output voltages Vₒᵤₜ provided by the circuit 300.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A circuit for generating a drive voltage comprising:
a voltage source;
a first current generating unit coupled to the voltage source and a ground for generating a first input current;
a comparing unit having a first input terminal, a second input terminal and an output terminal, wherein the first input terminal is coupled to the first current generating unit, the second input terminal is coupled to the output terminal, and an output voltage is generated by comparing the first input current with a second input current;
a second current generating unit coupled between the output terminal and the second input terminal of the comparing unit for generating the second input current; and
an adjusting unit coupled to the second input terminal of the comparing unit, the second current generating unit and the ground for adjusting the second input current,
wherein the output terminal of the comparing unit is an output terminal of the circuit for generating the drive voltage and the voltage level of the output voltage is controlled by the adjusting unit.

2. The circuit as claimed in claim 1, wherein the first current generating unit comprises at least two resistors connected in series.

3. The circuit as claimed in claim 1, wherein the second current generating unit comprises a resistor.

4. The circuit as claimed in claim 1, wherein the comparing unit is a comparator.

5. The circuit as claimed in claim 1, wherein the adjusting unit comprises:
at least one resistor having one terminal coupled to the ground;
at least one switch having one terminal coupled to the other terminal of the at least one resistor and other terminal coupled to the second input terminal of the comparing unit; and
a control circuit for generating at least one control signal to turn-on or turn-off the at least one switch and controlling the second input current.

6. The circuit as claimed in claim 1, wherein the circuit is provided for driving a liquid crystal display device and adjusting a display contrast of the liquid crystal display device.
